(19) United States
(12) Patent Application Publication
(10) Pub. No.: US 2012/0242420 A1
(43) Pub. Date: Sep. 27, 2012

(54) RESONANT FREQUENCY ADJUSTABLE OSCILLATION CIRCUIT

(75) Inventor: GUANG-FENG OU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/167,725

(22) Filed: Jun. 24, 2011

(30) Foreign Application Priority Data
Mar. 25, 2011 (CN) 201110073116.4

(51) Int. Cl. H03B 5/30

(52) U.S. Cl. 331/158

(57) ABSTRACT

An oscillation circuit includes a parallel resonant quartz crystal oscillator and a variable capacitor which are connected with each other in parallel. In addition, the oscillation circuit can further include a first variable resistor and a second variable resistor. The first resistor is connected to the quartz crystal oscillator in parallel. The second resistor is connected to the variable capacitor in series first and then connected to the quartz crystal oscillator in parallel.

### BACKGROUND

1. Technical Field

The present disclosure relates to oscillation circuits, and particularly, to an oscillation circuit of which the resonant frequency is adjustable.

2. Description of Related Art

Quartz crystal oscillators are widely used in various electronic devices to provide clock signals. Sometimes, it is desired to change the resonant frequency of the quartz crystal oscillators. However, the resonant frequency of the quartz crystal oscillators can not be adjusted. In addition, sometimes, it is also desired to change the resonant phase of the quartz crystal oscillators. However, the resonant phase of the quartz crystal oscillators cannot be adjusted either.

Therefore, it is desirable to provide an oscillation circuit, which can overcome the limitations described.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a circuit diagram of an oscillation circuit, according to an embodiment.

FIG. 2 is a circuit diagram of an equivalent circuit of a quartz crystal oscillator of the oscillation circuit of FIG. 1, according to the embodiment.

FIG. 3 is a graph showing a relationship between the impedance and the resonant frequency of the quartz crystal oscillator of FIG. 2, according to the embodiment.

FIG. 4 is a circuit diagram of a simulating circuit of the oscillation circuit of FIG. 1, according to the embodiment.

FIG. 5 is a graph showing waveforms of a timing signal generated by the simulating circuit of FIG. 4, according to the embodiment.

FIG. 6 is a circuit diagram of another simulating circuit of the oscillation circuit of FIG. 1, according to the embodiment.

FIG. 7 is a graph showing waveforms of a timing signal generated by the simulating circuit of FIG. 6, according to the embodiment.

### DETAILED DESCRIPTION

Embodiments of the present disclosure will now be described in detail with reference to the drawings.

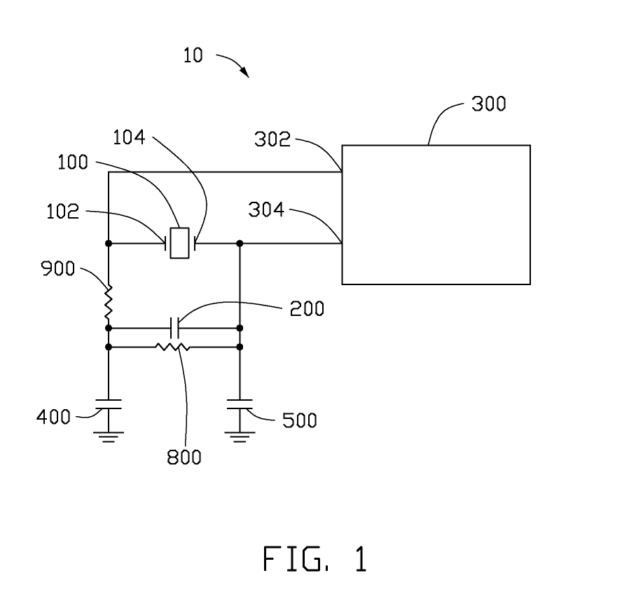

Referring to FIG. 1, an oscillation circuit 10, according to an embodiment, includes a parallel resonant quartz crystal oscillator 100 and a variable capacitor 200, which are connected with each other in parallel. The capacitance of the variable capacitor 200 is adjustable. For example, the capacitor 200 can be a varactor diode. An increased inverted voltage that is applied to the varactor diode is, increases the effective capacitance of the varactor diode. Thus, the capacitance of the variable capacitor 200 can be adjusted by changing the inverted voltage.

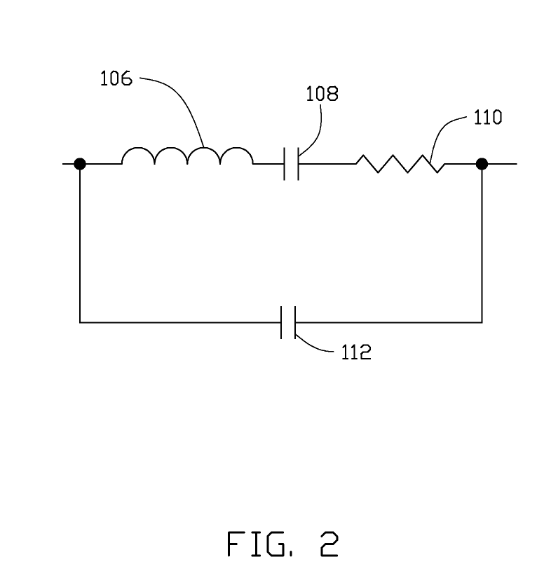

Referring to FIG. 2, an equivalent circuit of the oscillator 100 includes an inductor 106, a first capacitor 108, a resistor 110, and a second capacitor 112. The inductor 106, the first capacitor 108, and the resistor 110 are first connected in series, and then together connected with the second capacitor 112 in parallel.

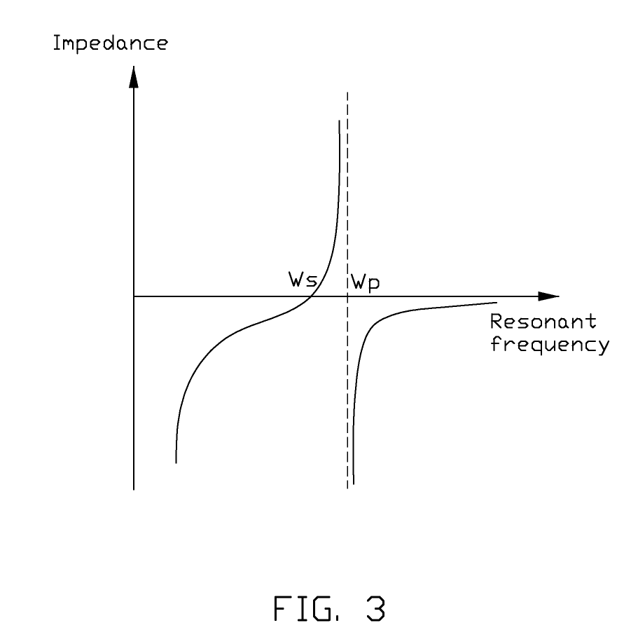

Referring to FIG. 3, a relationship between the impedance and the resonant frequency of the oscillator 100 is illustrated and satisfies the following formula:

$$Z = \frac{{( j w )}^{2} + j w \frac{{R}_{q}}{{L}_{q}} + {W}_{s}^{2}}{( j w \cdot {C}_{o} ) [ {( j w )}^{2} + j w \frac{{R}_{q}}{{L}_{q}} + {Wp}^{2} ]} ,$$

wherein Z is the impedance of the oscillator 100, j is the imaginary unit, w is the resonant frequency of the oscillator 100, Wₛ is a series frequency of the oscillator 100, Wₚ is a parallel frequency of the oscillator 100, the series frequency Wₛ satisfies the formula:

$${W}_{s} = \frac{1}{\sqrt{{L}_{q} \cdot {C}_{q}}} ,$$

the parallel frequency Wₚ satisfies the formula:

$${W}_{p} = \frac{1}{\sqrt{{L}_{q} \frac{{C}_{q} {C}_{o}}{{C}_{q} + {C}_{o}}}} ,$$

L_{q} is the inductance of the inductor 106, C_{q} is the capacitance of the first capacitor 108, R_{q} is the resistance of the resistor 110, and Cₒ is the capacitance of the second capacitor 112.

In this embodiment, the resonant frequency w of the oscillator 100 is the parallel resonant frequency Wₚ as the oscillator 100 is parallel resonates. Thus, the resonant frequency of the oscillation circuit 10 is partially determined by the parallel capacitance of the second capacitor 112 and the variable capacitor 200, that is, the capacitance C_{q} in the formula of the parallel frequency Wₚ is replaced with the parallel capacitance of the second capacitor 112 and the variable capacitor 200. As a result, the resonant frequency of the oscillation circuit 10 is adjustable as the capacitance of the variable capacitor 200 is variable/adjustable.

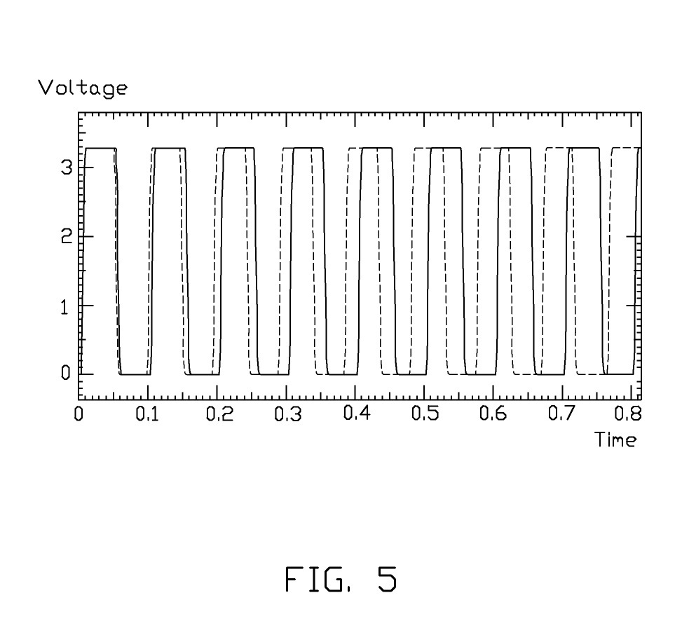

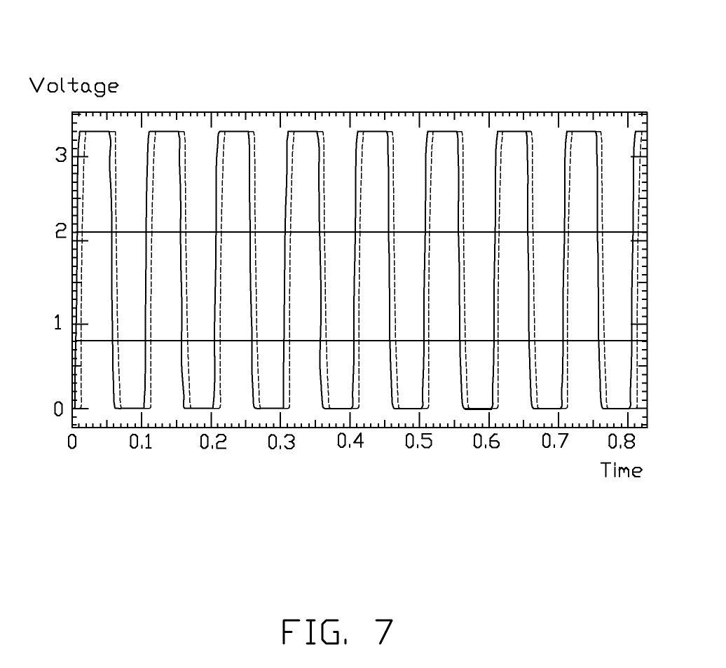

In particular, the oscillator 100 includes an input pin 102 and an output pin 104. The oscillator 100 can be actuated and starts the resonating after the input pin 102 receives a transient initial actuating signal/voltage. Then, the output pin 104 can keep outputting a timing signal (see FIGS. 5 and 7). In practice, the input pin 102 and the output pin 104 are connected to a clock generator 300 and are grounded through a third capacitor 400 and a fourth capacitor 500 respectively. The clock generator 300 includes an actuating pin 302 and a receiving pin 304. The actuating pin 302 is connected to the input pin 102. The receiving pin 304 is connected to the output pin 104. The clock generator 300 is configured for generating the actuating signal and providing the actuating signal to the oscillator 100 via the actuating pin 302 and the input pin 102 at the starting of the resonating of the oscillator 100. The clock generator 300 is also configured for processing, e.g., frequency dividing, the timing signal from the oscillator via the output pin 104 and the receiving pin 304 and thus forming various processed timing signals.

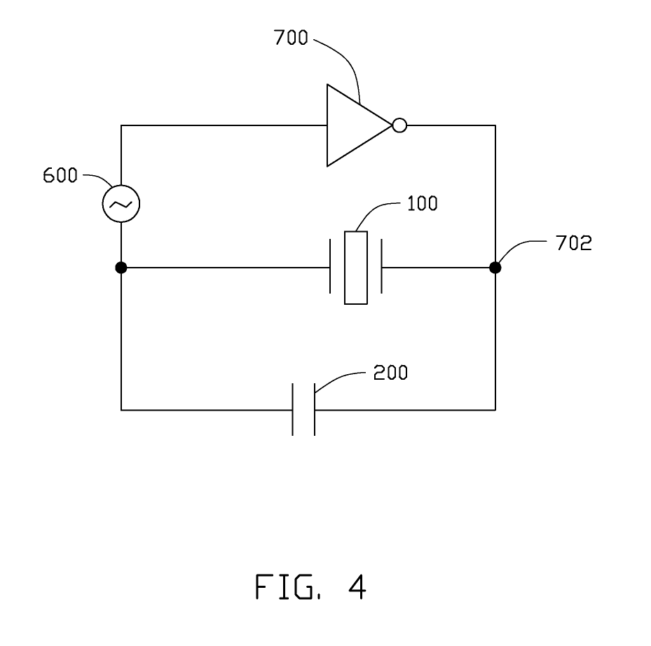

Referring to FIGS. 4 and 5, to prove that the resonant frequency of the oscillation circuit 10 does change when the capacitance of the variable capacitor 200 changes, simulating experiments are carried out. In the simulation, the clock generator 300 is modeled as an actuating source 600 and an inverter 700, that is, the actuating source 600 simulates the actuating function of the clock generator 300 and the inverter 700 simulates the frequency dividing function of the clock generator. Thus, the timing signal of the oscillation circuit 10 can be obtained by measuring a point 702, which is located between the inverter 700 and the oscillation circuit 10, by an oscillograph (not shown). As shown in FIG. 5, the solid curve and the dotted curve are waveforms of the timing signal, which are measured when the capacitance of the variable capacitor 200 is adjusted to about 13.5 pF and about 250 pF respectively. It can be found that the resonant frequency of the timing signal (the resonant frequency of the oscillation circuit 10) does change when the capacitance of the variable capacitor 200 changes.

By various simulations, it is also found that the resonant frequency of the oscillation circuit 10 can get a maximum adjustable range when the capacitance of the variable capacitor 200 critically ranges from about 0 pF to about 1000 pF. Therefore, it is beneficial that a variable range of the capacitance of the variable capacitor 200 is set to about 0-1000 pF.

The oscillation circuit 10 further includes a first variable resistor 800 and a second variable resistor 900. The first variable resistor 800 is connected to the oscillator 100 in parallel. The second variable resistor 900 is connected to the variable capacitor 200 in series first, and then connected with the oscillator 100 in parallel.

By simulating experiments, it can be found that the resonant phase of the oscillation circuit 10 changes as the resistance of the first variable resistor 800 and the second variable resistor 900 changes.

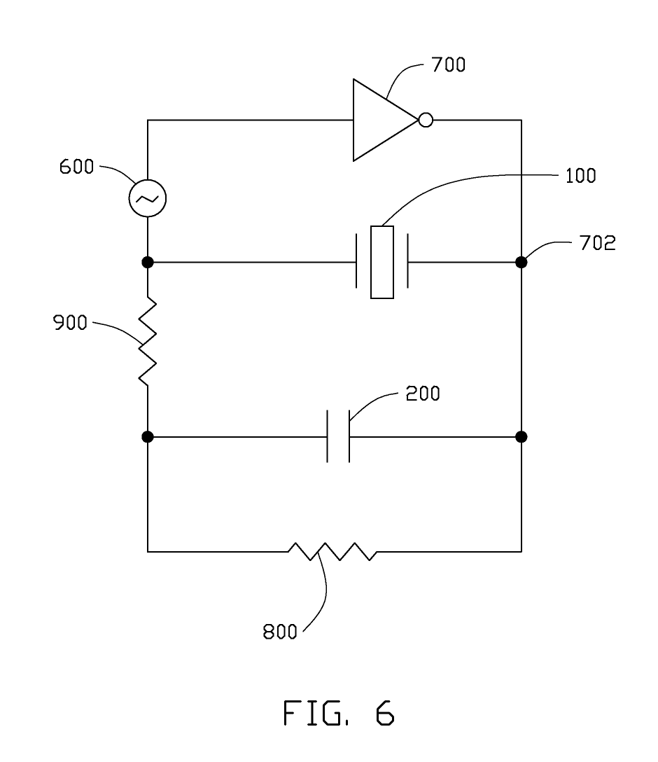

Referring to FIGS. 6 and 7, the solid curve and the dotted curve are waveforms of the timing signal, which are measured when the resistances of both the first variable resistor 800 and the second variable resistor 900 are adjusted to about 0Ω and when the resistances of the first variable resistor 800 and the second variable resistor 900 are adjusted to about 3 MΩ and about 30Ω respectively. It can be found that the resonant phase of the timing signal (the resonant phase of the oscillation circuit 10) does change when the resistances of the first variable resistor 800 and the second variable resistor 900 changes.

By various simulating experiments, it is also found that the resonant phase of the oscillation circuit 10 can get a maximum adjustable range when the resistance of the first variable resistor 800 is in the critical range from about 0Ω to about 10 MΩ and the resistance of the second variable resistor 900 is in the critical range from about 0Ω to about 100Ω. Therefore, it is beneficial that the variable ranges of the resistances of the first variable resistor 800 and the second variable resistor 900 are set to about 0-10 MΩ and about 0-100Ω respectively.

It will be understood that the above particular embodiments are shown and described by way of illustration only. The principles and the features of the present disclosure may be employed in various and numerous embodiment thereof without departing from the scope of the disclosure as claimed. The above-described embodiments illustrate the scope of the disclosure but do not restrict the scope of the disclosure.

What is claimed is:

1. An oscillation circuit, comprising:
a parallel resonant quartz crystal oscillator and a variable capacitor which are connected with each other in parallel.

2. The oscillation circuit of claim 1, wherein the variable capacitor comprises a varactor diode.

3. The oscillation circuit of claim 1, wherein a variable range of the capacitance of the variable capacitor is about 0-1000 pF.

4. The oscillation circuit of claim 1, further comprising a first variable resistor and a second variable resistor, the first resistor is connected to the quartz crystal oscillator in parallel, the second resistor is connected to the variable capacitor in series first and then connected to the quartz crystal oscillator in parallel.

5. The oscillation circuit of claim 1, wherein a variable range of the resistance of the first variable resistor is about 0-10 MΩ, and a variable range of the resistance of the second variable resistor is about 0-100Ω.
